(19) United States
(12) Patent Application Publication
(10) Pub. No.: US 2012/0243338 A1
(43) Pub. Date: Sep. 27, 2012

(54) NONVOLATILE SEMICONDUCTOR STORAGE DEVICE

(75) Inventor: Dai NAKAMURA, Fujisawa-shi (JP)

(73) Assignee: Kabushiki Kaisha Toshiba, Tokyo (JP)

(21) Appl. No.: 13/425,621

(22) Filed: Mar. 21, 2012

(30) Foreign Application Priority Data
Mar. 24, 2011 (JP) 2011-066395

(51) Int. Cl. G11C 16/04

(52) U.S. Cl. 365/185.29

(57) ABSTRACT

A nonvolatile semiconductor storage device of an embodiment includes: a cell array including a plurality of memory cells formed on a well and configured by a charge accumulating layer and a control gate; a plurality of control gate lines that are paths for supplying a voltage necessary to access the memory cells to the control gates of the memory cells; and an erasing circuit that performs an erasing operation configured by an erasing period during which data of the memory cells are erased and a resetting period during which a post processing of the erasing period is performed, the erasing circuit applying an erasing voltage necessary to erase the data to the well of the memory cells during the erasing period, and discharging the erasing voltage applied to the well of the memory cells to a ground line via the control gate lines during the resetting period.

### CROSS-REFERENCE TO RELATED APPLICATIONS

This application is based upon and claims the benefit of priority from the prior Japanese Patent Application No. 2011-66395, filed on Mar. 24, 2011, the entire contents of which are incorporated herein by reference.

### FIELD

Embodiments described herein relate to a nonvolatile semiconductor storage device.

### BACKGROUND

As a nonvolatile semiconductor storage device (EEPROM) capable of being electrically rewritten and highly integrated, a NAND-type flash memory is known. In the NAND-type flash memory, a plurality of memory cells serially connected in a manner that adjacent ones share a source/drain diffusion layer configures a NAND cell unit. Both ends of the NAND cell unit respectively are connected to a bit line and a source line via select gate transistors. By the NAND cell unit configuration as above, compared to a NOR type, a unit cell area can be smaller and a mass storage becomes possible.

In an erasing operation, the NAND-type flash memory applies an erasing voltage of about 20 V to a P-type well in which memory cells are formed (hereafter referred to as “CPWELL”). Then, in a selected block, a voltage of about 0 V is applied to word lines, and the memory cells are caused to be in an erased state by pulling out electrons from floating gates of the memory cells. On the other hand, in an unselected block, an erasure of the memory cells is prevented with a potential difference between the word lines and the CPWELL being made small by causing the word lines to be in a floating state.

Then, after having erased data from the memory cells, the erasing voltage that had been applied to the CPWELL is discharged to a ground line to prepare for the next operation. However, in so doing, there is a case in which the voltage of the unselected block drops due to an influence of coupling between the word lines and a cell source line, as well as the CPWELL and the bit lines. In this case, if the erasing voltage is not sufficiently discharged from the CPWELL, an erroneous erasure of memory cells occurs in the unselected block.

### BRIEF DESCRIPTION OF THE DRAWINGS

FIG. 1 is a diagram showing a configuration of a nonvolatile semiconductor storage device (NAND-type flash memory) of a first embodiment;

FIG. 2 is a diagram showing a configuration of a cell array of the nonvolatile semiconductor storage device of the embodiment;

FIG. 3 is a diagram explaining how word lines, floating gates and wells are in an erasing operation of the nonvolatile semiconductor storage device of the embodiment;

FIG. 4 is a diagram explaining how the word lines, the floating gates and the wells are in the erasing operation of the nonvolatile semiconductor storage device of the embodiment;

FIG. 5 is a connection diagram of the cell array, a control gate line driver and a well discharging circuit in the nonvolatile semiconductor storage device of the embodiment;

FIG. 6 is a circuit diagram of a control gate line driver of a nonvolatile semiconductor storage device of a comparative example;

FIG. 7 is a circuit diagram of a well discharging circuit of the nonvolatile semiconductor storage device of the comparative example;

FIG. 8 is a diagram explaining voltages of a cell array and the control gate line in an erasing operation of the nonvolatile semiconductor storage device of the comparative example;

FIG. 9 is a diagram explaining the voltages of the cell array and the control gate line in the erasing operation of the nonvolatile semiconductor storage device of the comparative example;

FIG. 10 is an operational waveform chart of a CPWELL and word lines in the erasing operation of the nonvolatile semiconductor storage device of the comparative example;

FIG. 11 is a circuit diagram of the control gate line driver of the nonvolatile semiconductor storage device of the embodiment;

FIG. 12 is an operational waveform chart of the cell array and the word lines in the erasing operation of the nonvolatile semiconductor storage device of the embodiment;

FIG. 13 is a circuit diagram of a control gate line driver of a nonvolatile semiconductor storage device of a second embodiment;

FIG. 14 is a circuit diagram of an equalizing circuit of the nonvolatile semiconductor storage device of the embodiment;

FIG. 15 is a circuit diagram of a control gate line driver of a nonvolatile semiconductor storage device of a third embodiment; and

FIG. 16 is an operational waveform chart of a CPWELL and word lines in an erasing operation of the nonvolatile semiconductor storage device of the embodiment.

### DETAILED DESCRIPTION

A nonvolatile semiconductor storage device of an embodiment includes: a cell array including a plurality of memory cells, each of memory cells formed on a well configured by a charge accumulating layer and a control gate; a plurality of control gate lines that are paths for supplying a voltage necessary to access the memory cells to the control gates of the memory cells; and an erasing circuit that performs an erasing operation configured by an erasing period during which data of the memory cells are erased and a resetting period during which a post processing of the erasing period is performed, the erasing circuit applying an erasing voltage necessary to erase the data of the memory cells to the well of the memory cells during the erasing period, and discharging the erasing voltage applied to the well of the memory cells to a ground line via the control gate lines during the resetting period.

Hereinbelow, the nonvolatile semiconductor storage device of the embodiment will be explained with reference to the drawings.

### First Embodiment

### Configuration of Nonvolatile Semiconductor Storage Device

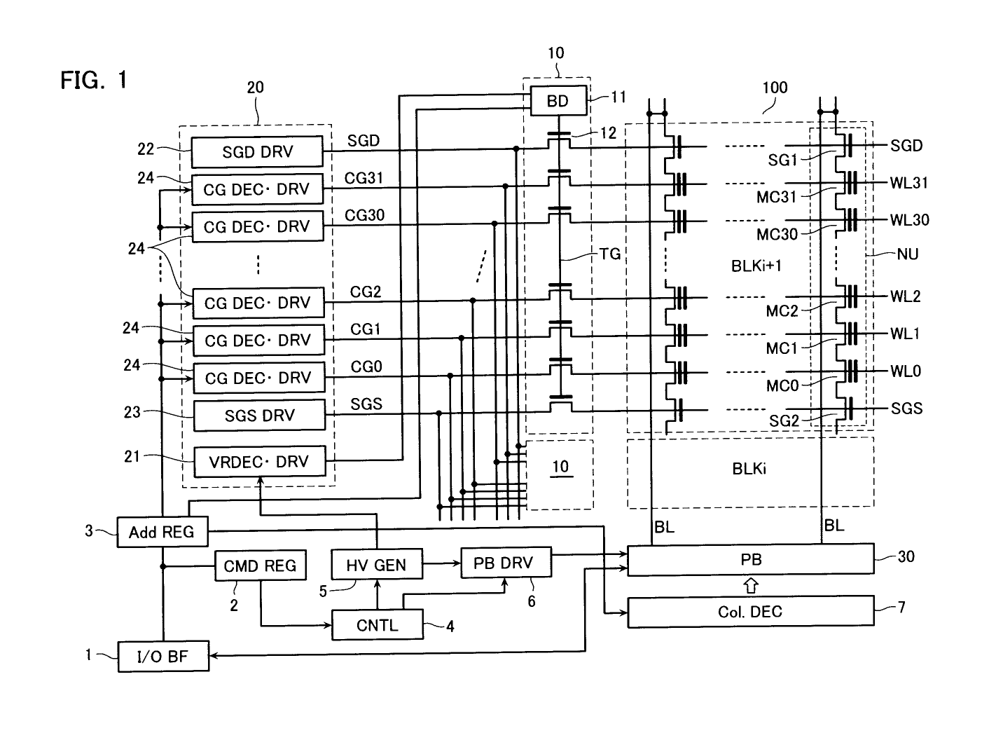

FIG. 1 is a schematic diagram of an overall configuration of a NAND-type flash memory (nonvolatile semiconductor storage device) of a first embodiment, and

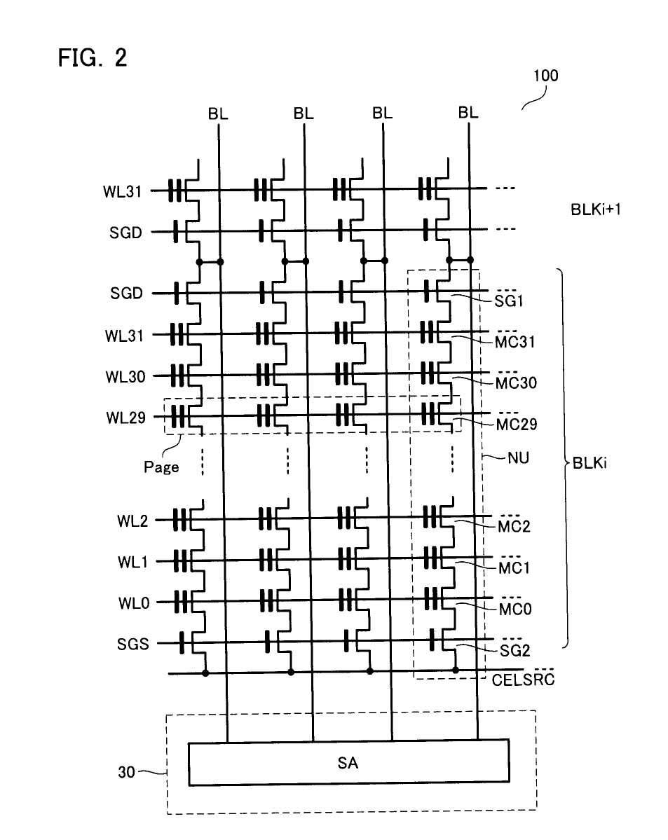

FIG. 2 is a diagram showing an equivalent circuit of its cell array 100. A NAND cell unit (NAND string) NU that is a basic unit of the NAND-type flash memory has a basic configuration of a plurality of memory cells MC0 to MC31 that are serially connected and two select transistors SG1, SG2 that are arranged on respective ends of the NAND cell unit NU.

As shown in FIG. 2, the NAND cell unit NU has its one end connected to a bit line BL via the select transistor SG1 and its other end connected to a source line CELSRC that is common within the cell array 100 via the select transistor SG2.

One memory cell MC has a silicon nitride film formed via a thin tunnel oxide film of about 2 nm on a semiconductor substrate as a charge accumulating layer, and has a MONOS structure in which a control gate is formed on this silicon nitride film via a gate insulating film. Further, the memory cell MC may have an N-type source/drain diffusion layer formed on a P-type well (hereafter referred to as “CPWELL”) of the silicon substrate, and may have a multilayer gate structure having a floating gate as the charge accumulating layer and control gates. The NAND-type flash memory stores 1 bit or multiple bits of data by changing a threshold voltage of the memory cell MC by changing an amount of charges retained in this silicon nitride film or the floating gate by writing operation and erasing operation.

The control gates of each of the memory cells MC0 to MC31 in the NAND cell unit NU are connected to different word lines WL0 to WL31, and gates of the select gate transistors SG1, SG2 are respectively connected to select gate lines SGD, SGS.

A set of NAND cell units NU sharing the word lines WL0 to WL31 and the select gate lines SGD, SGS configures a block BLK that is a unit for a flash erasure of data. Usually, as shown in the drawings, a plurality of blocks BLKi, BLKi+1, . . . is arranged in a bit line BL direction.

The NAND-type flash memory shown in FIG. 1 realizes various operations by accompanying command inputs. For example, in the writing operation, a data load command is latched from an input/output circuit 1 to a command register 2. Further, a write address is latched in an address register 3 via the input/output circuit 1, then write data is loaded to a page buffer circuit 30 via the input/output circuit 1. Thereafter, when a write execution command is latched in the command register 2 via the input/output circuit 1, the writing operation is automatically started internally.

That is, when the write execution command is input, a sequence control circuit 4 starts to operate. The sequence control circuit 4 performs a control of a voltage necessary for the writing operation, timing controls of a writing pulse applying operation and a verify read operation during the writing operation. This sequence control circuit 4 controls the respective circuits during the erasing operation in a manner similar to the writing operation, and configures an erasing circuit together with a row signal driving circuit 20 to be explained below.

A high-voltage generating circuit 5 is controlled by the sequence control circuit 4, and generates a high voltage (boosting voltage) such as a writing voltage Vpgm that is necessary for the row signal driving circuit 20 and a page buffer driver 6. Further, the high-voltage generating circuit 5 also generates an erasing voltage Vera to be applied to the CPWELL during the erasing operation.

The row signal driving circuit 20 includes as many control gate line decoder drivers 24 as the number of the word lines WL in the NAND cell unit NU, a drain side select gate line driver 22 that controls the drain side select gate line SGD, a source side select gate line driver 23 that controls the source side select gate line SGS, and a block decoder driver 21 for outputting a voltage that is boosted to a power node of a block decoder 11. These drivers 21 to 24 are shared among a plurality of blocks BLK of the memory cell array 100.

The NAND-type flash memory needs to operate by using a plurality of voltages on a plurality of word lines WL of the selected NAND cell unit NU. Thus, among row addresses, page addresses selecting the word lines WL in the NAND cell unit NU are input to each of the control gate line decoder drivers 24.

At a word line WL end of each block BLK of the cell array 100, a row decoder 10 in a narrow sense having a block selecting function is arranged. The row decoder 10 includes the block decoder 11 that receives a block address from the address register 3 and decodes the same, and transfer transistors 12 being commonly controlled by an output of this block decoder 11 to transfer the voltages necessary for writing, erasing and reading to the word lines WL and select gate lines SGD, SGS in the selected block BLK.

One end of each of the transfer transistors 12 is connected to an output of the drivers 22 to 24, and the other end is connected to the word lines WL and the select gate lines SGD, SGS in the cell array 100. For example, in the writing pulse applying operation, the writing voltage Vpgm (about 20 V) needs to be applied to the selected word lines. At this occasion, Vpgm+Vth supplied from the block decoder driver 21 (Vth being a voltage corresponding to a threshold of the transfer transistors 12) is applied to a common gate TG of the transfer transistors 12. Further, during the erasing operation, the transfer transistors 12 of the row decoder 10 connected to the selected block BLK to which the erasing operation is to be performed are caused to be in an ON state, and 0 V is applied to the word lines WL from the control gate lines CG. Further, the transfer transistors 12 of the row decoder 10 connected to the unselected blocks are caused to be in an OFF state, and the word lines WL of the unselected block BLK are brought to be in the floating state.

The NAND-type flash memory uses an FN tunnel current for the writing and erasing. Especially in the writing operation, the multiple memory cells can be written concurrently because the current necessary for a threshold shifting of one memory cell is very small, unlike the NOR type memory cells. Accordingly, a page length of the flash processing unit in the writing and reading can be made large, such as 2 Kbytes and 4 Kbytes. Sense amplifiers SA in the page buffer circuit 30 are at the same number as the page length.

A column decoder 7 decodes, for example in a case of loading the write data, column addresses sent from the address register 3, connects the selected sense amplifier SA to the input/output circuit 1, and sets the write data for each column address in the page buffer circuit 30. The reading operation is an inverse thereof, and data read in a flash manner to the page buffer circuit 30 is output from the sense amplifier SA selected according to the column addresses to the input/output circuit 1.

FIG. 2 shows an example in which the bit lines BL of each block BLK are connected to the sense amplifier SA in the page buffer circuit 30. Due to this sense amplifier SA, the writing operation or reading operation is controlled. At this occasion, memory cells commonly connected to one word line WL and selected by the bit lines BL configure one page that is the unit of concurrent writing or reading.

<Erasing Operation>

Here, the erasing operation of the NAND-type flash memory of the embodiment will be explained. Hereinbelow, a period in the erasing operation of actually erasing the data of the memory cells will be called the “erasing period”, and a period of resetting a bias state and the like in the cell array to prepare for the next operation after the erasing period will be called the “resetting period”.

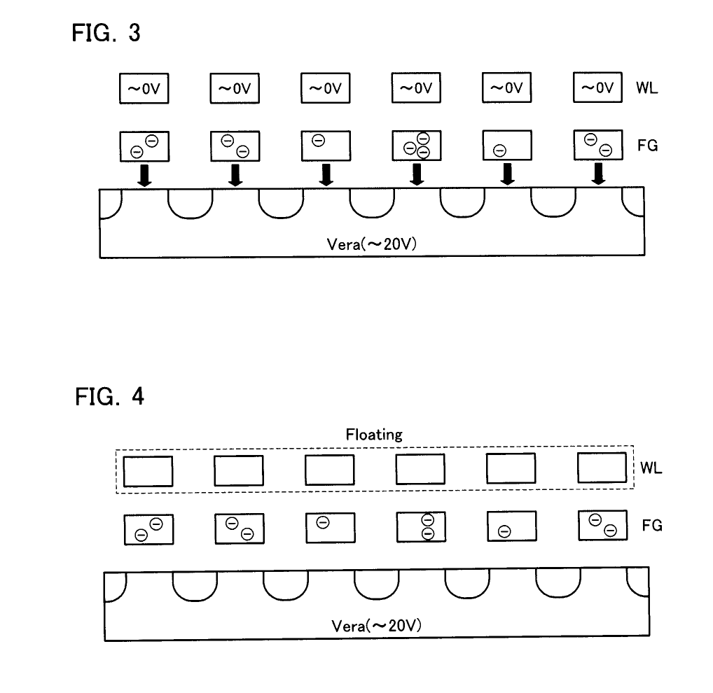

FIGS. 3 and 4 show how the word lines WL, floating gates FG and CPWELL are during the erasing period of the NAND-type flash memory of the embodiment. FIG. 3 shows an inside of the selected block, and FIG. 4 is an inside of the unselected block.

In erasing the data, the NAND-type flash memory applies the erasing voltage Vera of about 20 V to the CPWELL. Thereafter, as shown in FIG. 3, the voltage of about 0 V is applied to the word lines WL of the selected block. Due to this, the electrons that had been accumulated in the floating gates FG are pulled out to the CPWELL, and the threshold of the memory cells transit to an erased state. On the other hand, in the unselected block, as shown in FIG. 4 with a dotted line, the word lines WL are caused to be in the floating state. Accordingly, the word lines WL come to be close to the erasing voltage Vera due to the coupling with the CPWELL. As a result, the potential difference between the CPWELL and the word lines WL becomes small, and the electrons in the floating gates FG remain in the floating gates FG as they are; thus, the threshold of the memory cells does not transit to the erased state. From the above, data can be erased only from the memory cells in the selected block.

Next, the operation during the resetting period of the NAND-type flash memory of the embodiment will be explained together with an operation during a resetting period of a NAND-type flash memory of a comparative example.

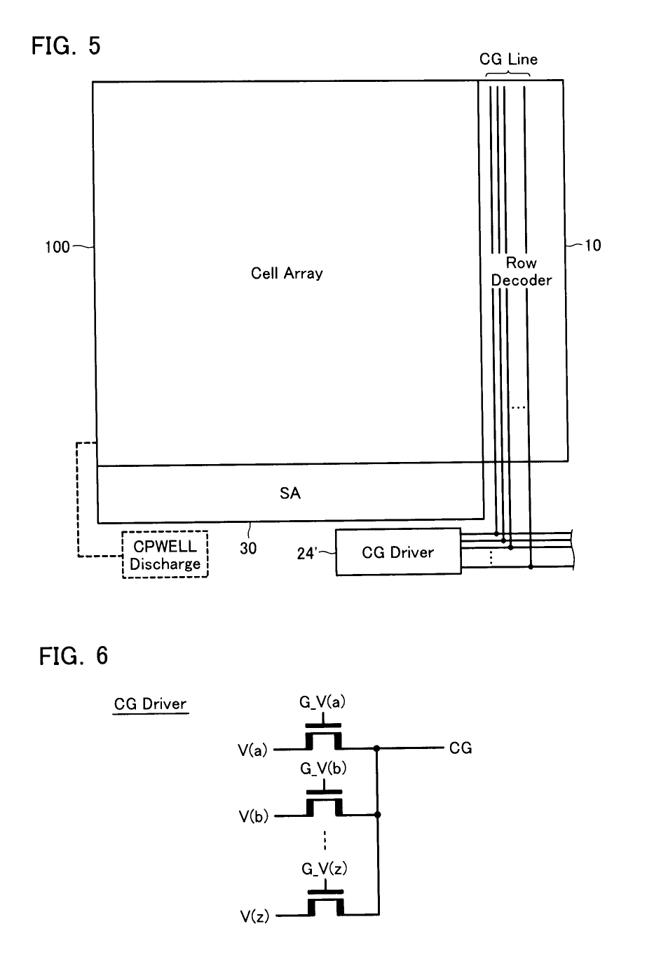

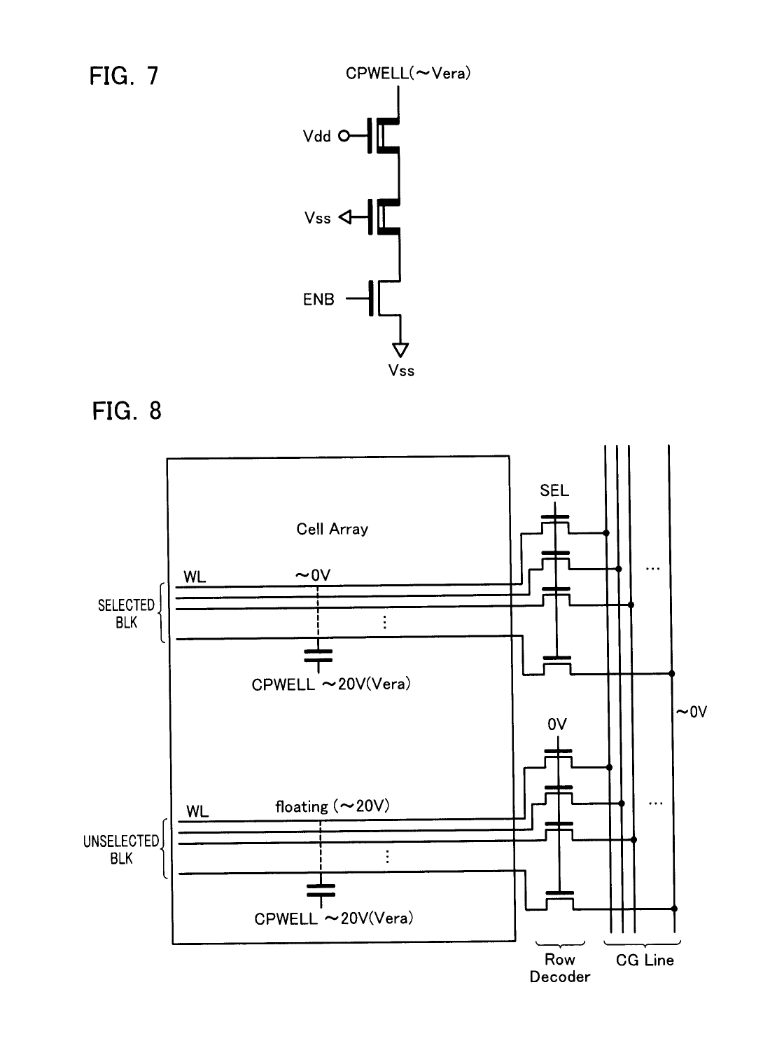

FIG. 5 is a connection diagram of the cell array of the NAND-type flash memory of the embodiment and the comparative example and peripheral circuits related to the erasing operation. Note that, a CPWELL discharging circuit (CPWELL Discharge) shown in FIG. 5 with a dotted line is a constituent element of the NAND-type flash memory of the comparative example, which is not required in the embodiment.

The NAND-type flash memory of the embodiment includes, as has been shown in FIG. 1, the cell array 100, the row decoder 10, the sense amplifier SA (page buffer circuit 30), and a control gate line driver (CG Driver) 24′ which is a part of the control gate line decoder drivers 24.

The NAND-type flash memory of the comparative example further includes, in addition to its configuration similar to the NAND-type flash memory of the embodiment, the CPWELL discharging circuit (CPWELL discharge) that discharges the voltage of the CPWELL of the cell array 100. Of these configurations, the control gate line driver 24′ of the embodiment and a control gate line driver of the comparative example differ in the followings.

FIG. 6 is a circuit diagram of the control gate line driver of the comparative example. The control gate line driver includes a plurality of depression type transistors. One ends of these depression type transistors are respectively connected to power sources with different voltages V(a), V(b), . . . , V(z), and the other ends are commonly connected to a control gate (CG) line. Further, control signals G_V(a), G_V(b), . . . , G_V(z) are input to gates of these depression type transistors, respectively. By these control signals G_V(a), G_V(b), . . . , G_V(z), the control gate line driver can supply the plurality of different voltages V(a), V(b), . . . , V(z) to the control gate lines CG.

The CPWELL discharging circuit includes two high voltage resistance depression type transistors serially connected from the CPWELL of the cell array to a ground line and a transistor that is controlled by an enable signal ENB. This enable signal ENB is a signal that activates the CPWELL discharging circuit.

Next, an operation of the NAND-type flash memory of the comparative example having the above configuration during a resetting period will be explained with reference to FIGS. 8 to 10.

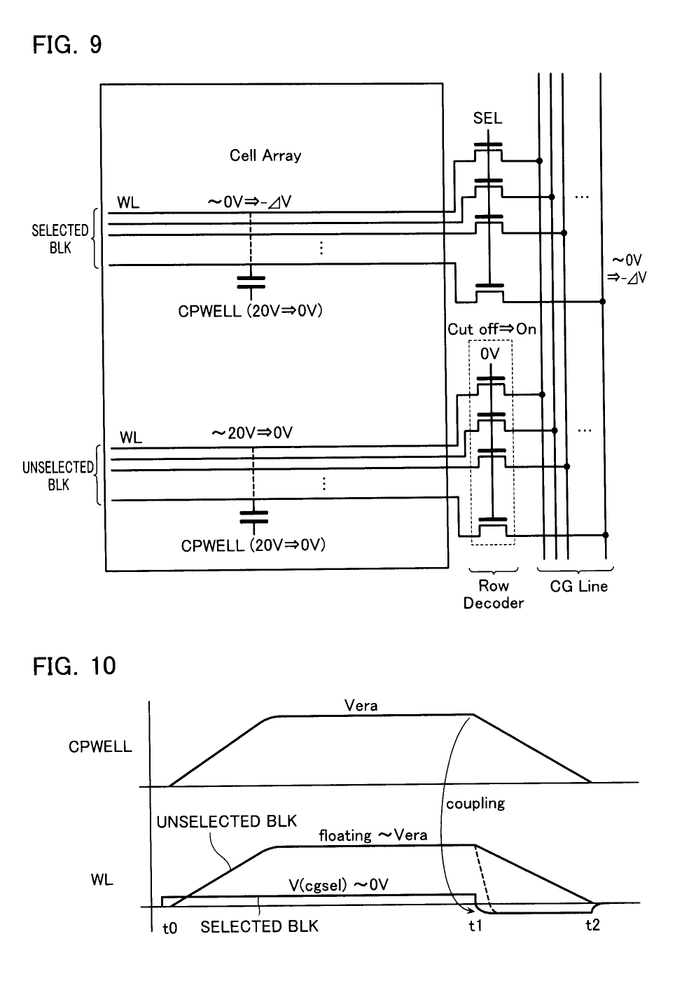

FIGS. 8 to 10 are diagrams related to the NAND-type flash memory of the comparative example, where FIG. 8 shows voltage states of the cell array and the control gate lines before starting the resetting period, FIG. 9 shows the voltage states of the cell array and the control gate lines during the resetting period, and FIG. 10 shows an operational waveform chart of the CPWELL and the word lines during an erasing operation, respectively.

First, during the erasing period of periods t0 to t1, the erasing voltage Vera of about 20 V is supplied to the CPWELL of the selected block and the unselected blocks.

Further, the row decoder transfer transistors connecting the selected block and the control gate lines are in an ON state by a block selecting signal SEL that is input to the gates (see FIG. 8). According to this, a voltage of about 0 V is supplied to the control gates of the memory cells of the selected block via the control gate lines (CG Line).

On the other hand, row decoder transfer transistors connecting the unselected blocks and the control gate lines are in an OFF state by the voltage of about 0 V that is input to the gates (see FIG. 8). According to this, the word lines WL of the unselected blocks come to be in a floating state. As a result, the voltage of the control gates CG rises to about 20 V that is about the same as the CPWELL (see FIG. 8). During the periods t0 to t2, data of the memory cells of the selected block are erased.

Subsequently, during the resetting period of periods t1 to t2, the erasing voltage Vera is discharged from the CPWELL.

However, in a case where a discharging speed of this erasing voltage Vera is fast, the word lines WL of the selected block drop from about 0 V to a negative voltage −ΔV by an influence of coupling of the CPWELL, cell source line and bit lines. In this case, the control gate lines also drop from about 0 V to a negative voltage −ΔV via the transfer transistors in the ON state between the selected block and the control gate lines. Due to this, the transfer transistors in the OFF state between the unselected blocks and the control gate lines come to be in the ON state even though the voltage of 0 V is supplied to the gates (FIG. 9).

In this case, in the voltage of the word lines WL of the unselected blocks, as shown in FIG. 10 with a dotted line, the voltage that had been at about the erasing voltage Vera of the word lines WL of the selected block is discharged. At this time, if the erasing voltage Vera of the CPWELL is not sufficiently discharged, a potential difference occurs between the control gates CG of the memory cells of the unselected blocks and the CPWELL. Then, if this potential difference is large, the memory cells of the unselected blocks are erroneously erased.

According to the above points, in the case of the NAND-type flash memory of the comparative example, the discharge of the erasing voltage Vera from the CPWELL needs to be moderated so that the word lines WL of the selected block do not abruptly drop by the influence of the coupling between the word lines WL and the CPWELL and the like. As a result, with the NAND-type flash memory of the comparative example, a processing time of the erasing operation becomes long.

Thus, in the NAND-type flash memory of the embodiment, the erasing voltage Vera of the CPWELL is discharged via the control gate lines during the resetting period of the erasing operation. Due to this, the control gate lines are prevented from dropping to the negative voltage, and during the resetting period, the transfer transistors between the unselected block and the control gate lines are prevented from being erroneously coming to be in the ON state.

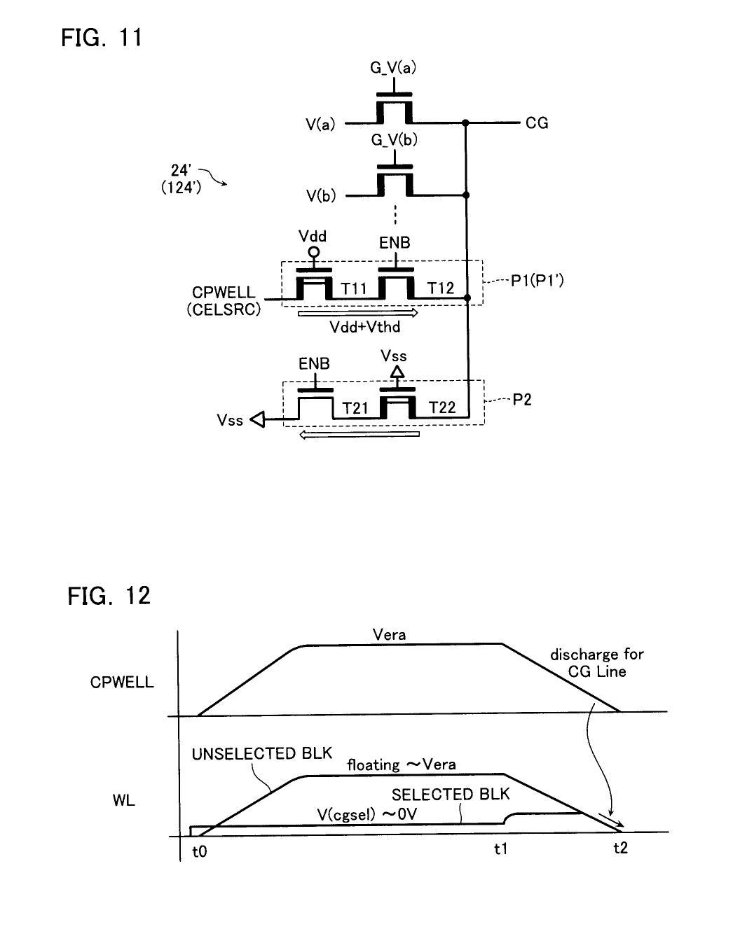

FIG. 11 is a circuit diagram of the control gate line driver 24′ of the NAND-type flash memory of the embodiment.

The control gate line driver 24′ has a configuration in which a discharging path (first discharging path) for discharging the erasing voltage Vera from the CPWELL to the ground line is further added to the control gate line driver of the NAND-type flash memory of the comparative example shown in FIG. 6.

This discharging path is configured by an inter-CPWELL-control gate line path P1 connecting the CPWELL and the control gate line, and an inter-control gate line-ground line path P2 connecting the control gate line and the ground line.

The inter-CPWELL-control gate line path P1 is configured with a high voltage resistance depression type transistor T11 that connects the power line of power voltage Vdd to a gate and a high voltage resistance enhancement type transistor T12 that activates the inter-CPWELL-control gate line path P1. The transistors T11 and T12 are serially connected. The transistor T11 is controlled by the enable signal ENB. Further, a threshold voltage of the transistor T11 is −Vthd.

On the other hand, the inter-control gate line-ground line path P2 is configured with a high voltage resistance depression type transistor T21 that connects the ground line to a gate and an enhancement type transistor T22 that activates the inter-control gate line-ground line path P2. The transistors T21 and T22 are serially connected. The transistor T21 is controlled by the enable signal ENB.

FIG. 12 is an operational waveform chart of the CPWELL and the word lines of the NAND-type flash memory of the embodiment during the erasing operation. Note that, even in the case with the embodiment also, since the erasing period of periods t0 to t1 is similar to the case with the comparative example shown in FIG. 10, the explanation thereof will be omitted. Note that, during the erasing period, the inter-CPWELL-control gate line path P1 and the inter-control gate line-ground line path P2 are not activated.

In the case with the embodiment, during the resetting period of periods t1 to t2, the inter-CPWELL-control gate line path P1 and the inter-control gate line-ground line path P2 are activated by the enable signal ENB. Due to this, a charge sharing via the inter-CPWELL-control gate line path P1 is performed, and the voltage of the control gate line rises to Vdd+Vthd as shown in FIG. 12. Therefore, the voltage drop in the control gate line by the influence of the coupling occurring in the word lines WL can be compensated, and the control gate line is prevented from coming to be at the negative voltage. In accordance with this, the voltage of the word lines WL in the selected block also rise. As a result, the transfer transistors between the unselected blocks and the control gates do not come to be in the ON state, and the memory cells in the unselected blocks being erroneously erased as in the comparative example can be avoided.

Thereafter, as shown in FIG. 12 with an arrow, the voltages of the word lines WL and the control gate lines of the selected block that had risen at time t1 change in accordance with the voltage decrease in the CPWELL, and drop to 0 V at a timing when the voltage of the CPWELL drops to 0 V (time t2).

Note that, in a case where a drive power of the control gate lines-CPWELL is excessively larger than a drive power of the inter-CPWELL-control gate line path P1, since the voltage of the control gate lines comes to be at about a ground voltage Vss, the influence of coupling by the discharging cannot be fully cancelled, and the control gate lines consequently drop to a negative voltage. Accordingly, it should be noted that a ratio of the drive power of the inter-CPWELL-control gate line path P1 and the drive power of the inter-control gate line-ground line path P2 should be adjusted to a degree by which the control gate lines do not come to have the negative voltage.

### Summary of the Embodiment

In the NAND-type flash memory of the comparative example, the control gate lines are fixed at a low voltage as the ground voltage Vss or close thereto by the control gate line driver during the resetting period. However, in this case, if the erasing voltage Vera is quickly discharged from the CPWELL, the control gate lines drop to the negative voltage by the influence of the coupling that occurs in the word lines WL, so there is a risk that the memory cells in the unselected blocks are erroneously erased. Accordingly, in the case with the NAND-type flash memory of the comparative example, the discharging speed of the erasing voltage Vera from the CPWELL cannot be accelerated efficiently.

In this regard, in the case of the embodiment, since the erasing voltage Vera of the CPWELL is discharged to the ground line via the control gate lines, the voltage drop of the control gate lines by the influence of the coupling that occurs in the word lines WL can be compensated by the erasing voltage Vera itself. Thus, according to the embodiment, unlike the comparative example, the erroneous erasure of the unselected blocks does not occur even if the discharging of the erasing voltage Vera is not moderated during the resetting period. As a result, compared to the comparative example, the resetting period can be shortened, which as a consequence can accelerate the erasing operation.

Further, in the embodiment, charging to the control gate lines is not performed from a new, different power source, but instead uses the erasing voltage Vera discharged from the CPWELL, so it can be realized without accompanying a substantial increase in a consumed current.

### Second Embodiment

In the first embodiment, as shown in FIG. 11, the inter-CPWELL-control gate line path P1 is provided in the control gate line driver 24′, but in a control gate line driver 124′ of the second embodiment, as shown in FIG. 11 within parentheses, an inter-cell source line-control gate line path P1′ is provided instead of the inter-CPWELL-control gate line path P1. Note that, configurations other than this control gate line driver 124′ are similar to those of the first embodiment. That is, a discharging path (second discharging path) is configured by the inter-cell source line-control gate line path P1′ and the inter-control gate line-ground line path P2.

In the case where the voltage of the CPWELL is higher than a voltage of the cell source line CELSRC, a forward connection is formed from the CPWELL toward the cell source line CELSRC. Due to this, current flows in from the CPWELL toward the cell source line CELSRC, and the voltage of the CPWELL and the voltage of the cell source line CELSRC are balanced. Thus, even in the case with this embodiment also, similar to the first embodiment, the erasing voltage Vera of the CPWELL is discharged to the control gate lines.

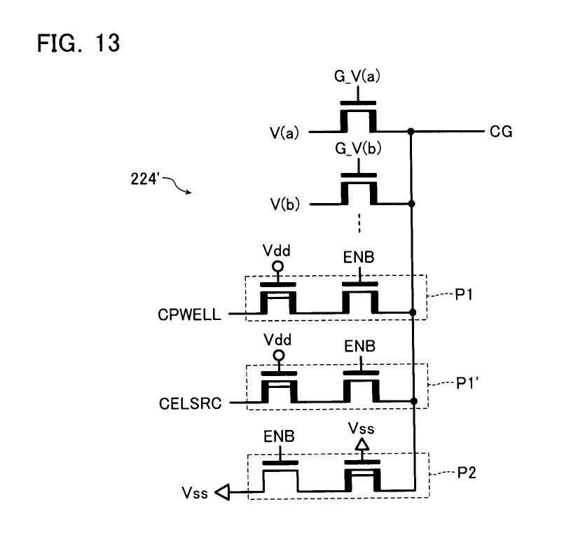

In the control gate line driver 124′ shown in FIG. 11, the inter-cell source line-control gate line path P1′ is provided instead of the inter-CPWELL-control gate line path P1; however, in the embodiment, as in a control gate line driver 224′ shown in FIG. 13, the new inter-cell source line-control gate line path P1′ may be provided separately from the inter-CPWELL-control gate line path P1.

Further, in a case of further providing an equalizing circuit as described later in the NAND-type flash memory, this equalizing circuit may be used as a replacement of the inter-cell source line-control gate line path P1′ and the inter-control gate line-ground line path P2.

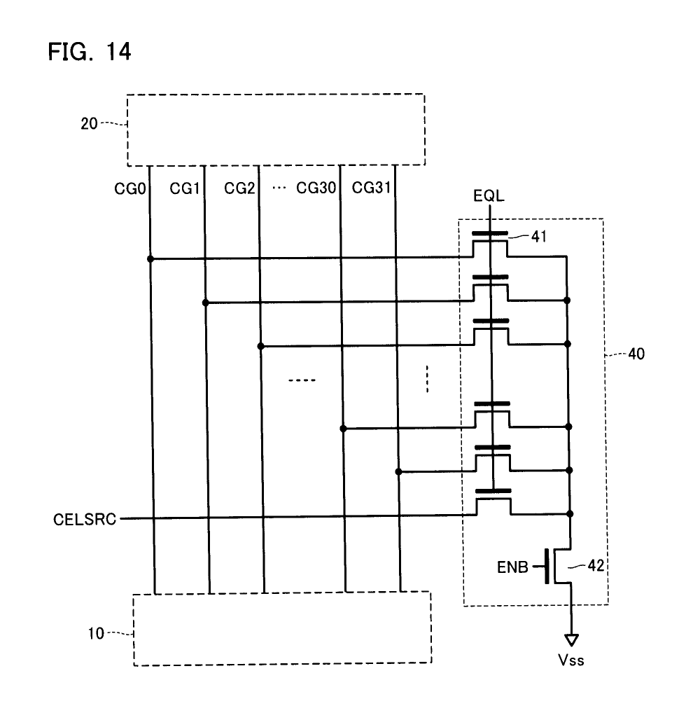

FIG. 14 is a diagram showing an example of the equalizing circuit.

The equalizing circuit 40 includes a plurality of transfer transistors 41 and a discharging transistor 42. The transfer transistors 41 are provided for each of the control gate lines CG0 to CG31 and the cell source line CELSRC. One ends of the transfer transistors 41 are connected to the control gate lines CG0 to CG31 and the cell source line CELSRC respectively, and the other ends are commonly connected to the ground line via the discharging transistor 42. An equalizing signal EQL is input to gates of all the transfer transistors 41. Further, in a gate of the discharging transistor 42, the enable signal ENB is input.

This equalizing circuit 40 is a circuit that causes the control gate lines CG0 to CG31 and the cell source line CELSRC to be at the same voltage during the writing operation and the reading operation, and discharges the voltages thereof. Specifically, the equalizing circuit 40 short circuits the control gate lines CG0 to CG31 and the cell source line CELSRC to cause them to be at the same voltage by an activation of the equalizing signal EQL, and thereafter discharges the voltages of the control gate lines CG0 to CG31 and the cell source line CELSRC to the ground line by an activation of the enable signal ENB.

With such an equalizing circuit 40, a path that reaches the control gate lines CG0 to CG31 from the cell source line CELSRC via the transfer transistors 41 of the equalizing circuit 40 may be used as the inter-cell source line-control gate line path P1′ shown in FIG. 11, and a path that reaches the ground line from the control gate lines CG0 to CG31 via the transfer transistors 41 and the discharging transistor 42 may be used as the inter-control gate line-ground line path P2 shown in FIG. 11.

Accordingly, in the case with the NAND-type flash memory having the equalizing circuit, by using this as the replacement of the discharging path, a similar effect as in the cases of using the control gate line drivers 124′, 224′ shown in FIGS. 11 and 13 can be obtained without causing an additional increase in a chip area. Note that, in using the equalizing circuit, a careful attention should be paid to voltage resistance of the discharging path.

Thus, according to the embodiment, similar to the first embodiment, the erasing operation can be accelerated without causing the erroneous erasure of the memory cells of the unselected blocks.

### Third Embodiment

A NAND-type flash memory of the third embodiment includes a plurality of inter-control gate line-ground line paths, and the number of the inter-control gate line-ground line paths to be activated is changed during the resetting period. According to this, a further acceleration of the erasing operation can be obtained as will be explained below.

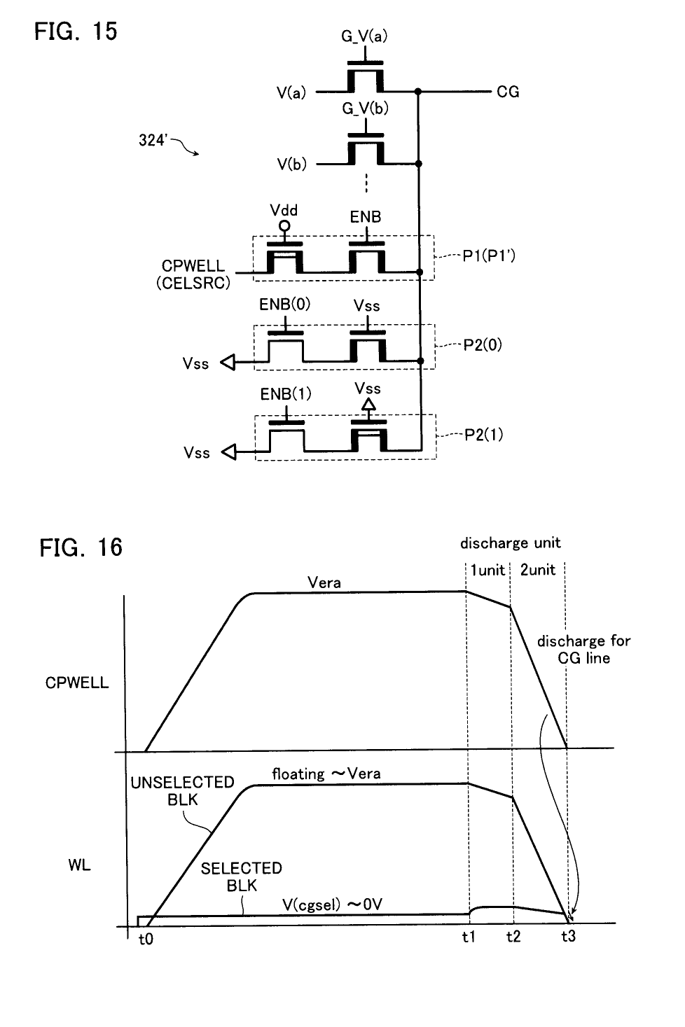

FIG. 15 is a circuit diagram of a control gate line driver 324′ of the NAND-type flash memory of the embodiment. Note that, configurations other than this control gate line driver 324′ are similar to those of the first embodiment.

The control gate line driver 324′ of the embodiment includes two inter-control gate line-ground line paths P2(0) and P2(1) that have similar configuration to the inter-control gate line-ground line path P2 of the control gate line driver 24′ shown in FIG. 11. These inter-control gate line-ground line paths P2(0), P2(1) are independently activated by enable signals ENB(0), ENB(1), respectively.

Note that, similar to the second embodiment, in this embodiment also, the inter-cell source line-control gate line path P1′ may be provided instead of the inter-CPWELL-control gate line path P1.

Next, an erasing operation of the NAND-type flash memory of the embodiment including this control gate line driver 324′ will be explained.

FIG. 16 is an operational waveform chart of the CPWELL and the word lines of the NAND-type flash memory of the embodiment. Note that, as for the erasing period of periods t0 to t1, it is similar to the first and second embodiments, so hereafter, a resetting period that is started from time t1 will be explained.

Periods t1 to t2 just after starting the resetting period are just after having started to discharge the erasing voltage Vera from the CPWELL, so the voltage of the control gate lines is low. Therefore, the control gate lines are made to be sufficiently charged by causing the drive power of the inter-control gate line-ground line path to be smaller than the drive power of the inter-CPWELL-control gate line path P1. Specifically, while activating the enable signal ENB(0), the enable signal ENB(1) is not activated. As a result, only the inter-control gate line-ground line path P2(0) is activated. Due to this, the drive power of the inter-control gate line-ground line path P2 can be made weak relative to the drive power of the inter-CPWELL-control gate line path P1. Note that, as shown in FIG. 16, the control gate lines and the word lines WL of the selected block rise their voltages without dropping to the negative voltage by the erasing voltage Vera being discharged to the control gate lines, similar to the first and second embodiments.

Then, during periods t2 to t3 after the control gate lines having been sufficiently charged, the inter-control gate line-ground line path P2(1) is activated by the enable signal ENB(1) in addition to the inter-control gate line-ground line path P2(0). Due to this, the drive power of the inter-control gate line-ground line path P2 is increased, and the discharging speed of the erasing voltage Vera from the CPWELL is accelerated. Due to this, the resetting period can be shortened. Note that, as shown in FIG. 16, by accelerating the discharge of the erasing voltage Vera, the voltage drop occurs in the control gate lines and the word lines WL of the selected block by the influence of the coupling; however, during periods t1 to t2, since the control gate lines are charged to a sufficient voltage of Vdd+Vth, a drop to the negative voltage does not occur despite some degree of voltage drop.

Thereafter, as shown in FIG. 16 with an arrow, the voltages of the word lines WL and the control gate lines of the selected block that had risen at time t1 change in accordance with the voltage drop in the CPWELL, and drop to 0 V at a timing when the voltage of the CPWELL drops to 0 V (time t3).

According to the above, in the case of the embodiment, by adjusting the drive power of the inter-control gate line-ground line path P2 according to the change in the voltage of the control gate lines or the CPWELL, the discharging speed can be slowed down when the voltage of the control lines starts to drop, or the discharging speed can be accelerated when the voltage drop of the CPWELL progresses and the risk of erroneous erasure becomes small. Thus, according to the embodiment, length of the resetting period can be optimally adjusted, and according to this, further acceleration of the erasing operation can be obtained than in the first and second embodiments.

### OTHERS

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a cell array including a plurality of memory cells, each of the memory cells formed on a well and configured by a charge accumulating layer and a control gate;
a plurality of control gate lines that are paths for supplying a voltage necessary to access the memory cells to the control gates of the memory cells; and
an erasing circuit that performs an erasing operation configured by an erasing period during which data of the memory cells are erased and a resetting period during which a post processing of the erasing period is performed,
the erasing circuit applying an erasing voltage necessary to erase the data of the memory cells to the well of the memory cells during the erasing period, and discharging the erasing voltage applied to the well of the memory cells to a ground line via the control gate lines during the resetting period.

2. The nonvolatile semiconductor storage device according to claim 1, wherein
the erasing circuit includes a control gate line driver that supplies the voltage necessary to access the memory cells to the control gates of the memory cells via the control gate lines, and
the control gate line driver includes a first discharging path for discharging the erasing voltage applied to the well of the memory cells to the control gate lines.

3. The nonvolatile semiconductor storage device according to claim 2, wherein
the control gate line driver adjusts a discharging speed of the erasing voltage applied to the well of the memory cells by switching drive power of the first discharging path.

4. The nonvolatile semiconductor storage device according to claim 1, wherein
the cell array includes a cell source line coupled to the well of the memory cells, and
the erasing circuit discharges the erasing voltage applied to the well of the memory cells to the control gate lines via the cell source line during the resetting period.

5. The nonvolatile semiconductor storage device according to claim 1, wherein
the cell array includes a cell source line coupled to the well of the memory cells, and
the erasing circuit includes an equalizing circuit that discharges the voltages of the plurality of control gate lines and the cell source line to a ground line after short circuiting the plurality of control gate lines and the cell source line, and the erasing circuit discharges the erasing voltage applied to the well of the memory cells to the control gate lines via the equalizing circuit during the resetting period.

6. The nonvolatile semiconductor storage device according to claim 1, wherein
during the resetting period, the voltage of the control gate lines drops accompanying a drop of the erasing voltage applied to the well.

7. The nonvolatile semiconductor storage device according to claim 2, wherein
the control gate line driver includes a plurality of the first discharging paths, and
each of the first discharging paths is activated independent of one another.

8. A nonvolatile semiconductor storage device comprising:
a cell array including a plurality of memory cells, each of the memory cells formed on a well and configured by a charge accumulating layer and a control gate;
a plurality of control gate lines that are paths for supplying a voltage necessary to access the memory cells to the control gates of the memory cells; and
an erasing circuit that performs an erasing operation configured by an erasing period during which data of the memory cells are erased and a resetting period during which a post processing of the erasing period is performed,
the erasing circuit applying an erasing voltage necessary to erase the data of the memory cells to the well of the memory cells during the erasing period, and discharging the erasing voltage applied to the well of the memory cells to the control gate lines during the resetting period.

9. The nonvolatile semiconductor storage device according to claim 8, wherein
the erasing circuit includes a control gate line driver that supplies the voltage necessary to access the memory cells to the control gate of the memory cells via the control gate lines, and
the control gate line driver includes a first discharging path for discharging the erasing voltage applied to the well of the memory cells to the control gate lines.

10. The nonvolatile semiconductor storage device according to claim 9, wherein
the control gate line driver adjusts a discharging speed of the erasing voltage applied to the well of the memory cells by switching drive power of the first discharging path.

11. The nonvolatile semiconductor storage device according to claim 8, wherein
the cell array includes a cell source line coupled to the well of the memory cells, and
the erasing circuit discharges the erasing voltage applied to the well of the memory cells to the control gate lines via the cell source line during the resetting period.

12. The nonvolatile semiconductor storage device according to claim 8, wherein
the cell array includes a cell source line coupled to the well of the memory cells,
the erasing circuit includes an equalizing circuit that short circuits the plurality of control gate lines and the cell source line, and the erasing circuit discharges the erasing voltage applied to the well of the memory cells to the control gate lines via the equalizing circuit during the resetting period.

13. The nonvolatile semiconductor storage device according to claim 8, wherein
during the resetting period, the voltage of the control gate lines drops accompanying a drop of the erasing voltage applied to the well.

14. The nonvolatile semiconductor storage device according to claim 9, wherein
the control gate line driver includes a plurality of the first discharging paths, and
each of the first discharging paths is activated independent of one another.

15. A nonvolatile semiconductor storage device comprising:
a cell array including a plurality of memory cells, each of the memory cells formed on a well and configured by a charge accumulating layer and a control gate;
a plurality of control gate lines that are paths for supplying a voltage necessary to access the memory cells to the control gates of the memory cells; and
an erasing circuit that performs an erasing operation configured by an erasing period during which data of the memory cells are erased and a resetting period during which a post processing of the erasing period is performed,
the erasing circuit including a first discharging path that electrically connects the well of the memory cells and the control gate lines during the resetting period.

16. The nonvolatile semiconductor storage device according to claim 15, wherein
the first discharging path is configured by a depression type transistor that is ON-controlled during the resetting period.

17. The nonvolatile semiconductor storage device according to claim 15, wherein
the erasing circuit adjusts a discharging speed of the erasing voltage applied to the well of the memory cells by switching drive power of the first discharging path.

18. The nonvolatile semiconductor storage device according to claim 15, wherein
the cell array includes a cell source line coupled to the well of the memory cells, and
the erasing circuit includes a second discharging path that electrically connects the cell source line and the control gate lines during the resetting period.

19. The nonvolatile semiconductor storage device according to claim 15, wherein
the cell array includes a cell source line coupled to the well of the memory cells, and
the erasing circuit includes an equalizing circuit that short circuits the plurality of control gate lines and the cell source line, and the erasing circuit discharges the erasing voltage applied to the well of the memory cells to the control gate lines via the equalizing circuit during the resetting period.

20. The nonvolatile semiconductor storage device according to claim 15, wherein
the erasing circuit includes a plurality of the first discharging paths, and each of the first discharging paths is activated independent of one another.
